(19) United States
(12) Patent Application Publication
(10) Pub. No.: US 2026/0177626 A1
(43) Pub. Date: Jun. 25, 2026

(54) INTERFACE FOR ONLINE ESTIMATION OF EQUIVALENT CIRCUIT MODEL PARAMETERS OF A BATTERY

(71) Applicant: Cirrus Logic International Semiconductor Ltd., Edinburgh (GB)

(72) Inventors: Hengsi QIN, Austin, TX (US); Samuel P. EBENEZER, Gilbert, AZ (US); Narayan KOVVALI, Tempe, AZ (US); Seth SUPPAPPOLA, Tempe, AZ (US)

(73) Assignee: Cirrus Logic International Semiconductor Ltd., Edinburgh (GB)

(21) Appl. No.: 19/376,144

(22) Filed: Oct. 31, 2025

Related U.S. Application Data
(60) Provisional application No. 63/868,079, filed on Aug. 21, 2025.

(30) Foreign Application Priority Data
Nov. 12, 2024 (JP) 2024-197129
Jul. 25, 2025 (JP) 2025-124654

(51) Int. Cl. G01R 31/367

(52) U.S. Cl. CPC G01R 31/367

(57) ABSTRACT

A method may include publishing, by an online estimator to a host device, estimated equivalent circuit model parameters of a battery and publishing, by the online estimator to the host device, statistics indicative of prevailing operating conditions of the battery.

### RELATED APPLICATIONS

The present disclosure claims priority to U.S. Provisional Patent Application Ser. No. 63/868,079, filed Aug. 21, 2025, which is incorporated by reference herein in its entirety.

The present disclosure is also related to United States Patent Publication No. 2024/0133957, United States Patent Publication No. 2025/0180651, United States Patent Publication No. 2025/0180652, and United States Patent Publication No. 2025/0180653, all of which are incorporated by reference herein in their entireties.

### FIELD OF DISCLOSURE

The present disclosure relates in general to circuits for electronic devices, including without limitation personal portable devices such as wireless telephones and media players, and more specifically, to online characterization of equivalent circuit model parameters of a battery and an interface for publishing such equivalent circuit model parameters.

### BACKGROUND

Portable electronic devices, including wireless telephones, such as mobile/cellular telephones, tablets, cordless telephones, mp3 players, and other consumer devices, are in widespread use. Such a portable electronic device may include a battery (e.g., a lithium-ion battery) for powering components of the portable electronic device. Those of skill in the art will recognize that a battery may comprise a single cell or multiple cells.

In operation, the terminal voltage of a battery may droop under a load current due to internal output impedance of the battery. Such output impedance may be modeled in a number of suitable manners, including with an equivalent circuit model of a series of parallel-coupled resistors and capacitors. Knowledge of the detailed impedance of a battery may be useful for fuel-gauging algorithms (e.g., for determining a battery open-circuit voltage, state of health, state of charge, monitoring aging, predicting power limits, and/or deriving safety limits or safe operation limits of the battery (e.g., a maximum voltage across battery terminals and maximum current of the battery)).

There may exist advantages in using a system load current drawn from a battery in order to perform in-situ characterization of parameters of the equivalent circuit model, as such an approach avoids time-consuming offline characterization. Offline characterization also does not generalize well, because of wide operating condition requirements, cell-to-cell variability, as well as variations in device usage behavior that affects age-dependent impedance.

However, spectrally-rich stimulus may be required to accurately estimate equivalent circuit model parameters online, and system load current is not guaranteed to contain spectrally-rich content at all times. Further, a battery is a highly non-linear dynamic system and the battery behavior may change as a function of load current amplitude. The ECM parameters may have to be adjusted as a function of load current amplitude. It may not be possible to estimate these current amplitude-dependent model parameters online if high load current is not drawn from the battery.

Various solutions exist for estimating impedance for a battery, including those solutions set forth in the patent publications described in the “RELATED APPLICATIONS” section above. United States Patent Publication No. 2024/0133957 provides an example method for estimating the linear battery impedance. United States Patent Publication No. 2025/0180651 introduces that the battery impedance may be a function of load current, shows the need to have current dependent battery impedance, and provides a solution that continuously tracks the dynamic load current level and the corresponding impedance parameters in a table. United States Patent Publication No. 2025/0180652 provides a solution for estimating the current dependent battery impedance parameter by using augmentation high current pulses. However, traditional solutions do not provide an interface to report estimated battery parameters to a battery management system.

### SUMMARY

In accordance with the teachings of the present disclosure, one or more disadvantages and problems associated with existing approaches to modeling a battery (e.g., with an equivalent circuit model or physics-based model) may be reduced or eliminated.

In accordance with embodiments of the present disclosure, a method may include publishing, by an online estimator to a host device, estimated equivalent circuit model parameters of a battery and publishing, by the online estimator to the host device, statistics indicative of prevailing operating conditions of the battery.

In accordance with these and other embodiments of the present disclosure, an online estimator may include one or more inputs configured to receive measurements of physical quantities associated with a battery and processing circuitry configured to publish to a host device, estimated equivalent circuit model parameters of the battery and publish to the host device, statistics indicative of prevailing operating conditions of the battery.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example power delivery network, in accordance with embodiments of the present disclosure;

FIG. 2 illustrates an example graph of an open circuit voltage of a battery versus the battery's state of charge, in accordance with embodiments of the present disclosure;

FIG. 3 illustrates a circuit diagram of selected components of an equivalent circuit model for a battery, in accordance with embodiments of the present disclosure;

FIG. 4 illustrates an example ECM publishing system for publishing data and parameters for an ECM, in accordance with embodiments of the present disclosure;

FIG. 5 illustrates an example online ECM estimator interfaced with and providing estimated battery ECM parameters to portions of a host device, in accordance with embodiments of the present disclosure;

FIG. 6 illustrates a flow chart of an example method that an estimator may execute in an on-demand mode for performing a single ECM estimation when enabled by a host device, in accordance with embodiments of the present disclosure; and

FIG. 7 illustrates a flow chart of an example method that an estimator may execute in a continuous mode for performing an ECM estimation continually when enabled by a host device, in accordance with embodiments of the present disclosure.

### DETAILED DESCRIPTION

Embodiments of the present disclosure may provide systems and methods for interfacing with a system that estimates an equivalent circuit model (ECM) of a battery in a system configured to provide a load. A load current and terminal voltage of a battery may be measured. The battery ECM may be estimated online using the measured terminal voltage and the load current. A lithium-ion battery may be a non-linear dynamic system. The impedance of a battery may change as a function of state-of-charge (SOC), temperature, state-of-health (SOH), and a load current of the battery. The interface may enable the ECM estimator to publish the estimated battery ECM parameters along with load current statistics (e.g., an average value of a prevailing battery current and a measure of variation of the prevailing battery current). In addition, the interface may enable publishing of an indicator of validity of the estimated ECM (e.g., a goodness of fit) and an indicator of validity of the battery current. The interface may also allow configuration of the battery ECM estimation to be performed either on-demand or continuously. In the case of on-demand configuration, the estimated ECM parameters may be published once the estimated ECM is indicated as valid. In the case of continuous configuration, the estimated ECM parameters may be published at a cadence or frequency set through a preset parameter.

FIG. 1 illustrates a block diagram of selected components of an example power delivery network 10, in accordance with embodiments of the present disclosure. In some embodiments, power delivery network 10 may be implemented within a portable electronic device, such as a smart phone, tablet, game controller, and/or other suitable device.

As shown in FIG. 1, power delivery network 10 may include a battery 12 and a load 18. As shown in FIG. 1, when loaded by load 18, battery 12 may generate a battery voltage V_{CELL} across its terminals and deliver a battery current I_{CELL} to load 18. In some embodiments, battery 12 may comprise a lithium-ion battery. Load 18 may represent any electric component, electronic component, and/or combination thereof. For example, load 18 may include any suitable functional circuits or devices of power delivery network 10, including without limitation power converters, processors, audio coder/decoders, amplifiers, display devices, etc. Further, although not explicitly shown in FIG. 1, power delivery network 10 may also include control circuitry for controlling operation of battery 12 and/or load 18.

As also shown in FIG. 1, power delivery network 10 may include battery monitoring circuitry 20. Battery monitoring circuitry 20 may include any suitable system, device, or apparatus configured to monitor battery voltage V_{CELL} and battery current I_{CELL}. Further, battery monitoring circuitry 20 may include a battery model estimator 24 configured to monitor battery voltage V_{CELL} and a sense voltage V_{RSNS} across a sense resistor 22 indicative of battery current I_{CELL}, and based thereon, estimate a battery impedance model for battery 12, as described in greater detail below. Battery model estimator 24 may be implemented with a processing device, including without limitation a microprocessor, digital signal processor, application-specific integrated circuit, field-programmable gate array, electrically-erasable programmable read only memory, complex programmable logic device, and/or other suitable processing device. In some embodiments, battery monitoring circuitry 20 may monitor a temperature associated with battery 12, and battery model estimator 24 may estimate the impedance model based on battery voltage V_{CELL}, a battery current I_{CELL}, and the sensed battery temperature.

As further shown in FIG. 1, power delivery network 10 may further include a dependent current source 26 controlled by battery model estimator 24 and configured to generate an augmented current I_{AUG}.

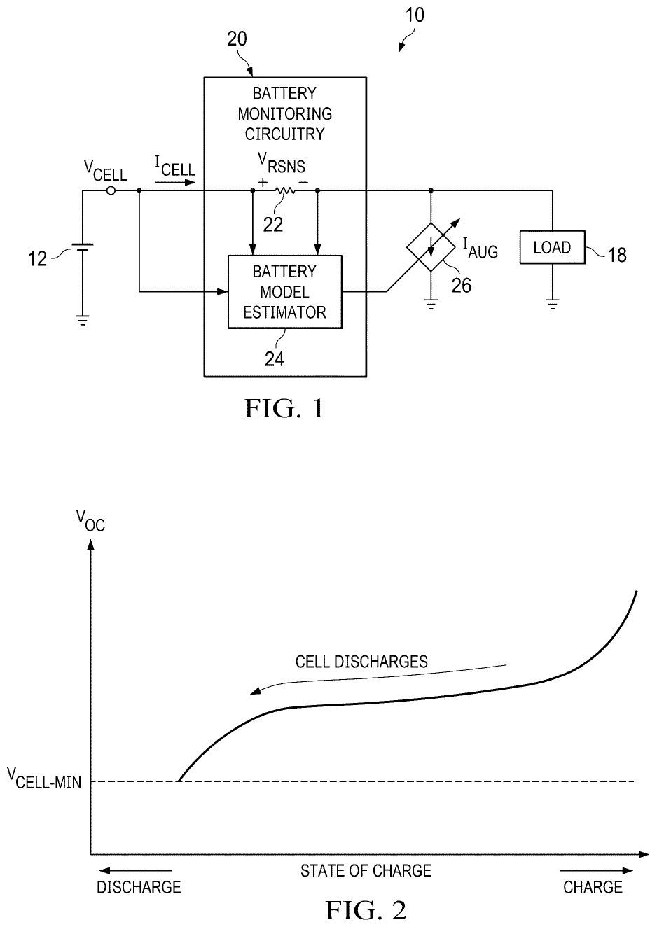

Lithium-ion batteries (e.g., battery 12) have an open circuit voltage V_{OC} (the voltage when load is not present) that depends on their chemistry, for example from 4.5 V when full to 3.0 V when empty. As a battery discharges due to a current drawn from the battery, the state of charge of the battery may also decrease, and open circuit voltage V_{OC} (which may be a function of state of charge) may also decrease as a result of electrochemical reactions taking place within the battery, as shown in FIG. 2. Operating outside the range of 3.0 V and 4.5 V for open circuit voltage V_{OC}, the capacity, life, and safety of a lithium-ion battery may degrade. For example, at approximately 3.0 V, approximately 95% of the energy in a lithium-ion cell may be spent, and open circuit voltage V_{OC} would be liable to drop rapidly if further discharge were to continue. Below approximately 2.4 V, metal plates of a lithium-ion battery may erode, which may cause higher internal impedance for the battery, lower capacity, and potential short circuit. Thus, to protect a battery (e.g., battery 12) from over-discharging, many portable electronic devices may prevent operation below a predetermined end-of-discharge voltage. Knowledge of the output impedance may be useful in determining open circuit voltage V_{OC} and other parameters of battery 12.

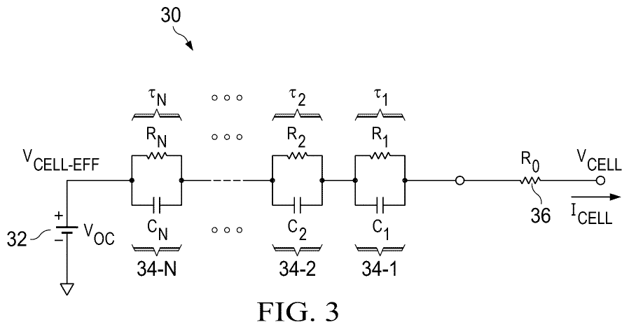

FIG. 3 illustrates a block diagram of selected components of an ECM 30 for battery 12, in accordance with embodiments of the present disclosure. As shown in FIG. 3, battery 12 may be modeled as having a battery cell 32 having an open circuit voltage V_{OC} in series with a plurality of parallel resistive-capacitive sections 34 (e.g., parallel resistive-capacitive sections 34-1, 34-2, . . . , 34-N) and further in series with an equivalent series resistance 36 of battery 12 (e.g., resistance R₀). Resistances R₁, R₂, . . . R_{N}, and respective capacitances C₁, C₂, . . . , C_{N} may model battery electrochemical process-dependent time constants τ₁, τ₂, . . . , τ_{N}, that may be lumped with open circuit voltage V_{OC} and equivalent series resistance 36. The series of impedance sections represented by resistive-capacitive sections 34 and equivalent series resistance 36 may represent diffusion, charge transfer, solid-electrolyte inter, and ohmic processes that occur at different rates inside battery 12. Cutoff frequencies of parallel resistive-capacitive sections 34 may respectively be given by:

$$\begin{matrix}{f}_{c 1} = \frac{1}{{τ}_{1}} = \frac{1}{2 π {R}_{1} {C}_{1}} ; \\ {f}_{c 2} = \frac{1}{{τ}_{2}} = \frac{1}{2 π {R}_{2} {C}_{2}} ; \\ … \\ {f}_{c N} = \frac{1}{{τ}_{N}} = \frac{1}{2 π {R}_{N} {C}_{N}} ;\end{matrix}$$

wherein π represents the well-known mathematical constant defined as the ratio of a circle's circumference to its diameter, and wherein parallel resistive-capacitive sections 34 are ordered such that f_{cN}< . . . <f_{c2}<f_{c1}. In some embodiments, the battery ECM (e.g., ECM 30) may be non-linear and the model parameters may be load current dependent.

Notably, an electrical node depicted with voltage V_{CELL-EFF} in FIG. 3 may capture the time varying discharge behavior of battery 12, and battery voltage V_{CELL} may be an actual voltage seen across the output terminals of battery 12. Voltage V_{CELL-EFF} may not be directly measurable, and thus battery voltage V_{CELL} may be the only voltage associated with battery 12 that may be measured to evaluate battery state of health. Also of note, at a current draw of zero (e.g., I_{CELL}=0), battery voltage V_{CELL} may be equal to voltage V_{CELL-EFF} which may in turn be equal to an open circuit voltage V_{OC} at a given state of charge, provided that enough time has passed with the current at zero, such that all of the voltages on capacitors of resistive-capacitive sections 34 have discharged to zero.

Battery behavior may change due to various factors, including temperature, state of charge, charge/discharge current amplitude, and age. Changes in such factors may change the state of the battery, and these dynamic factors may result in corresponding changes in parameter values of the equivalent circuit model 30. Parameters of the equivalent circuit model 30 may be used to assess battery condition, predict future voltage, and/or perform other battery management tasks.

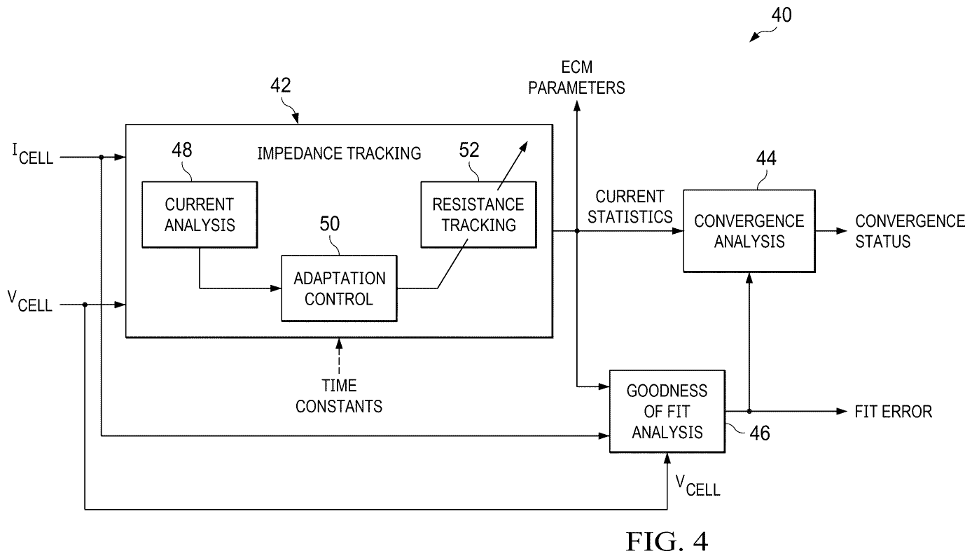

FIG. 4 illustrates an example ECM publishing system 40 for publishing diagnostic data and parameters for an ECM (e.g. ECM 30), in accordance with embodiments of the present disclosure. As shown in FIG. 4, ECM publishing system 40 may include an impedance tracking block 42, a convergence analysis block 44, and a goodness of fit analysis block 46.

As also shown in FIG. 4, impedance tracking block 42 may include a current analysis block 48, a resistance tracking block 52, and an adaptation control block 50. In operation, impedance tracking block 42 may receive as inputs battery voltage V_{CELL} and battery current I_{CELL}. Impedance tracking block 42 may also receive other ECM inputs including, but not limited to, a number of resistor-capacitor (“RC”) time constants and RC time constant values; a voltage error threshold for a valid ECM estimation; an ECM mode selection between two operating modes (e.g., an on-demand mode and a continuous mode); and an ECM update rate for configuring an update periodicity when ECM is enabled in the continuous mode.

Based on the received ECM inputs, current analysis block 48 may determine an indication of validity of the measurement for battery current I_{CELL}, and impedance tracking block 42 may publish the indication of validity of the measurement for battery current I_{CELL} (e.g., to a host device). Also based on the received ECM inputs, impedance tracking block 42 may determine load current statistics that represent a prevailing battery current and may publish such load current statistics (e.g., to a host device). The load current statistics may include an average current of the prevailing battery current, a measurement of variation of the prevailing battery current, and/or any other suitable statistics.

Adaptation control block 50 may comprise any system, device, or apparatus configured to cause an update of ECM parameters when sensed current I_{CELL} IS Of Sufficient signal-to-noise ratio.

Resistance tracking block 52 may comprise an estimator for estimating ECM parameters for battery 12, and impedance tracking block 42 may publish ECM parameters for battery 12. Battery ECM parameters may include, without limitation, a battery cell effective voltage, a battery series resistance and RC resistances and capacitances, and a battery flex cable resistance.

Convergence analysis block 44 may receive outputs from impedance tracking block 42 and based thereon, determine a convergence status that identifies a validity of the estimated ECM. Goodness of fit analysis block 46 may receive as inputs sensed battery voltage V_{CELL}, sensed current I_{CELL}, an indication of the validity of sensed current I_{CELL} and based thereon, determine a voltage fitting error FIT ERROR and publish voltage fitting error FIT ERROR (e.g., to a host device).

In some embodiments, ECM publishing system 40 may publish voltage fitting error FIT ERROR and the goodness of fit of the ECM parameters in the following manner. First, a host device may configure the voltage error threshold for a valid ECM estimation. Second, ECM 30 may use sensed battery current I_{CELL} and estimated ECM parameters to predict predicted battery voltage V_{PCELL}. Then, goodness of fit analysis block 46 may calculate voltage fitting error FIT ERROR between predicted battery voltage V_{PCELL} and measured battery voltage V_{CELL} based on a root-mean-square (RMS) error metric. Subsequently, a goodness of fit indication based on the RMS voltage fitting error and the host-configured voltage error threshold may be determined, and the voltage fitting error FIT ERROR and goodness of fit indicator may be published (e.g., reported to the host device).

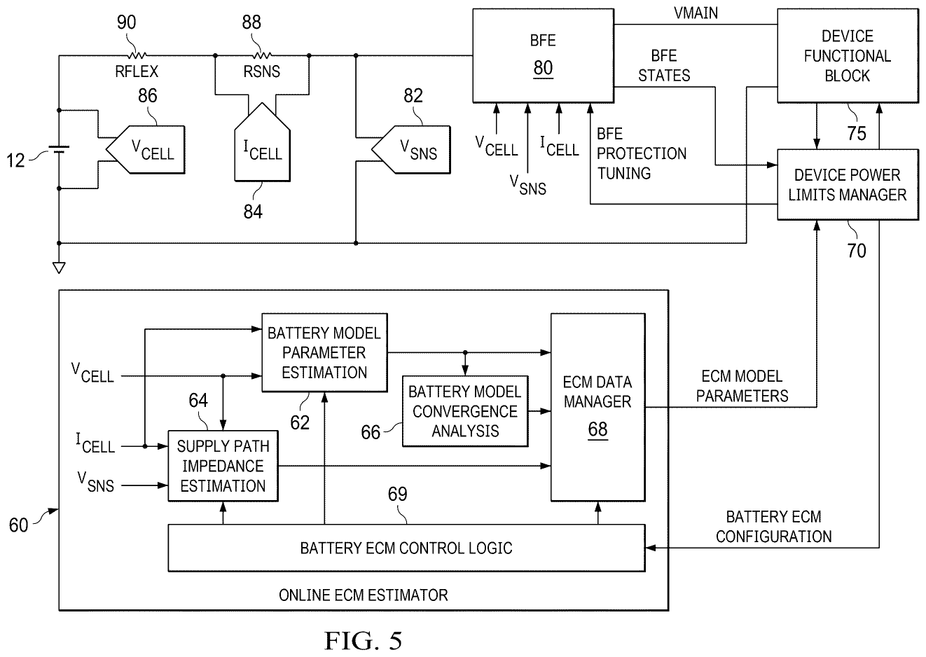

FIG. 5 illustrates an example of an online ECM estimator 60 interfaced with and providing estimated battery ECM parameters to portions of a host device (e.g., a smart phone), in accordance with embodiments of the present disclosure. As shown in FIG. 5, online ECM estimator 60 may include a battery model parameter estimation block 62, a supply path impedance estimation block 64, a battery model convergence analysis block 66, an ECM data manager block 68, and a battery ECM control logic block 69. The portions of the host device (e.g., smart phone) shown in FIG. 5 include a device power limits manager block 70, a device functional block 75 (e.g., that may include various functions/data such as device load information, a graphics processing unit, an applications processor, radios, touchscreen, and audio playback circuitry), a battery front end (BFE) block 80, a sensed voltage block VSNS 82, a sensed current block I_{CELL} 84, and a cell voltage V_{CELL} block 86. Sensed current block I_{CELL} 84 may be coupled to a sense resistor 88. A flex circuit may be modeled with an effective resistance 90 coupled via one of its terminals to a terminal of battery 12 and via another of its terminals to a node shared by sense resistor 88 and sensed current block I_{CELL} 84. Device functional block 75 and BFE block 80 may be coupled to a main voltage V_{MAIN}.

In operation, online ECM estimator 60 may output ECM battery model parameters to device power limits manager block 70. Device power limits manager block 70 may also receive functional data/information from device functional block 75 and BFE states from BFE block 80. Device power limits manager block 70 may provide its output to device functional block 75 and may also provide a BFE protection tuning output to BFE block 80 that may be used to tune BFE protection. BFE block 80 may also receive as inputs battery voltage V_{CELL}, sensed voltage VSNS, and the sensed current I_{CELL}.

Device power limits manager 70 may further provide its battery ECM configuration output to battery ECM control logic block 69. Battery ECM configuration output may include among its data/information an indication/signal that determines and sets whether the online ECM estimator 60 is to operate in an on-demand mode or in a continuous mode.

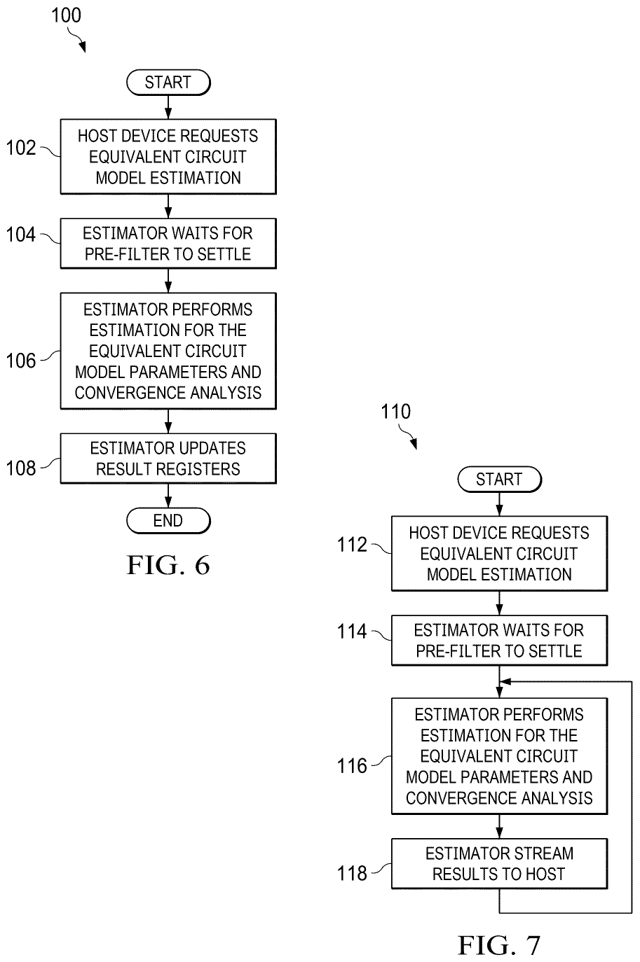

FIG. 6 illustrates a flow chart of an example method 100 that an estimator (e.g., resistance tracking block 52) may execute in an on-demand mode for performing a single ECM estimation when enabled by a host device, in accordance with embodiments of the present disclosure. According to certain embodiments, method 100 may begin at step 102. As noted above, teachings of the present disclosure may be implemented in a variety of configurations by ECM publishing system 40 as shown in FIG. 4. As such, the preferred initialization point for method 100 and the order of the steps comprising method 100 may depend on the implementation chosen.

At step 102, a host device may request an ECM estimation. At step 104, the estimator may wait for a pre-filter of sensed battery current I_{CELL} and sensed battery voltage V_{CELL} to settle down. At step 106, the estimator may perform estimation for the ECM parameters and perform convergence analysis. At step 108, the estimator may update result registers with the estimated ECM. The ECM estimation may begin after the sensed battery current I_{CELL} and sensed battery voltage V_{CELL} pre-filters settle. In some embodiments, method 100 may take approximately 5-iMax to complete, where τ_{MAX} is the maximum time constant specified by the host device for the battery ECM estimation.

Although FIG. 6 discloses a particular number of steps to be taken with respect to method 100, it may be executed with greater or lesser steps than those depicted in FIG. 6. In addition, although FIG. 6 discloses a certain order of steps to be taken with respect to method 100, the steps comprising method 100 may be completed in any suitable order.

Method 100 may be implemented using ECM publishing system 40, components thereof, or any other suitable system operable to implement method 100. In certain embodiments, method 100 may be implemented partially or fully in software and/or firmware embodied in computer-readable media.

FIG. 7 illustrates a flow chart of an example method 110 that an estimator (e.g., resistance tracking block 52) may execute in a continuous mode for performing ECM estimation continuously when enabled by a host device, in accordance with embodiments of the present disclosure. In the continuous mode, the estimator may keep performing ECM estimation as long as enabled by a host device to do so. According to certain embodiments, method 110 may begin at step 112. As noted above, teachings of the present disclosure may be implemented in a variety of configurations by ECM publishing system 40 as shown in FIG. 4. As such, the preferred initialization point for method 110 and the order of the steps comprising method 110 may depend on the implementation chosen.

At step 112, a host device may request an ECM estimation. At step 114, the estimator may wait for a pre-filter of sensed battery current I_{CELL} and sensed battery voltage V_{CELL} to settle down. At step 116, the estimator may perform estimation for the ECM parameters and perform convergence analysis. At step 118, the estimator may stream estimation results to the host device. After step 118, method 110 may proceed again to step 116, provided that the host device has not disabled ECM estimation. The ECM estimation may begin after the sensed battery current I_{CELL} and sensed battery voltage V_{CELL} pre-filters settle. In some embodiments, method 110 may take approximately 5·τ_{MAX} to complete. In some embodiments, the estimator may update results at a frequency configured by the host device.

Although FIG. 7 discloses a particular number of steps to be taken with respect to method 110, it may be executed with greater or lesser steps than those depicted in FIG. 7. In addition, although FIG. 7 discloses a certain order of steps to be taken with respect to method 110, the steps comprising method 110 may be completed in any suitable order.

Method 110 may be implemented using ECM publishing system 40, components thereof, or any other suitable system operable to implement method 110. In certain embodiments, method 110 may be implemented partially or fully in software and/or firmware embodied in computer-readable media.

Embodiments of the present disclosure may provide a method of publishing an estimated ECM of a battery along with load current statistics that represent a prevailing battery current, an indicator of validity of the estimated ECM, and an indicator of validity of the battery current. The load current statistics may comprise an average value of a prevailing battery current and a measure of variation of the prevailing battery current. The indicator of validity of the estimated ECM may be based on the goodness of fit of the estimated ECM. The goodness of fit of the estimated ECM may be defined by a voltage fitting error. Alternately, the goodness of fit of the estimated ECM may be defined by a relative error metric comprised of the ratio of the voltage fitting error and the voltage measurement noise level. The indicator of validity of the battery current may be defined by a measure of spectral content of the battery current. Alternatively, the indicator of validity of the battery current may be defined by a measure of conditioning of the battery current data.

Other embodiments of the present disclosure may provide a method of configuring and publishing the estimation of a battery ECM, wherein the ECM estimation may be configured to be performed on-demand or wherein the ECM estimation may be configured to be performed continuously. When the ECM estimation is configured to be performed on-demand (i.e., in an on-demand mode), the estimated ECM is published once the ECM is indicated as valid. Alternately, when the ECM estimation is configured to be performed continuously (i.e., in a continuous mode), the estimated ECM is published at a preset periodicity.

Further embodiments of the present disclosure may provide both a method of publishing an estimated ECM of a battery along with load current statistics that represent a prevailing battery current, an indicator of validity of the estimated ECM, and an indicator of validity of the battery current and a method of configuring and publishing the estimation of a battery ECM, wherein the ECM estimation may be configured to be performed on-demand or wherein the ECM estimation may be configured to be performed continuously.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A method comprising:
publishing, by an online estimator to a host device, estimated equivalent circuit model parameters of a battery; and
publishing, by the online estimator to the host device, statistics indicative of prevailing operating conditions of the battery.

2. The method of claim 1, wherein the statistics represent a prevailing current of the battery.

3. The method of claim 1, wherein the statistics represent an indication of validity of the estimated equivalent circuit model parameters.

4. The method of claim 3, wherein the indication of validity of the estimated equivalent circuit model parameters is based on a goodness of fit of the estimated equivalent circuit model.

5. The method of claim 4, wherein the goodness of fit of the estimated equivalent circuit model parameters is defined by a voltage fitting error between a measured battery voltage and a predicted battery voltage.

6. The method of claim 4, wherein the goodness of fit of the estimated equivalent circuit model is defined by a relative error metric comprised of the ratio of the voltage fitting error and the voltage measurement noise level.

7. The method of claim 1, wherein the statistics represent an indication of validity of a measured battery current.

8. The method of claim 1, wherein the statistics represent an average value of a prevailing current of the battery and a measure of variation of the prevailing current.

9. The method of claim 1, wherein the indicator of validity of the battery current is defined by a measure of spectral content of the battery current and a measure of conditioning of the battery current data.

10. The method of claim 1, wherein the estimation of the equivalent circuit model parameters may be configured to be performed on-demand or continuously.

11. The method of claim 10, wherein when the estimation of the equivalent circuit model parameters is configured to be performed on-demand, the estimated equivalent circuit model parameters are published once the estimated equivalent circuit model is indicated to be valid.

12. The method of claim 10, wherein when the estimation of the equivalent circuit model parameters is configured to be performed continuously, the estimated equivalent circuit model parameters are published at a preset periodicity.

13. The method of claim 1, wherein the equivalent circuit model parameters comprise resistances associated with time constants of the equivalent circuit model.

14. The method of claim 13, wherein the equivalent circuit model parameters further comprise capacitances associated with time constants of the equivalent circuit model.

15. The method of claim 1, further comprising using the equivalent circuit model parameters in a predictive model to determine available power or a maximum current that can be drawn from the battery at a given moment in time.

16. The method of claim 1, further comprising using the equivalent circuit model parameters in a predictive model to determine an extent of battery aging.

17. The method of claim 1, further comprising tracking nonlinear current-dependent equivalent circuit model parameters in a continuous manner.

18. An online estimator comprising:
one or more inputs configured to receive measurements of physical quantities associated with a battery; and
processing circuitry configured to:
publish to a host device, estimated equivalent circuit model parameters of the battery; and
publish to the host device, statistics indicative of prevailing operating conditions of the battery.

19. The online estimator of claim 18, wherein the statistics represent a prevailing current of the battery.

20. The online estimator of claim 18, wherein the statistics represent an indication of validity of the estimated equivalent circuit model parameters.

21. The online estimator of claim 20, wherein the indication of validity of the estimated equivalent circuit model parameters is based on a goodness of fit of the estimated equivalent circuit model.

22. The online estimator of claim 21, wherein the goodness of fit of the estimated equivalent circuit model parameters is defined by a voltage fitting error between a measured battery voltage and a predicted battery voltage.

23. The online estimator of claim 21, wherein the goodness of fit of the estimated equivalent circuit model is defined by a relative error metric comprised of the ratio of the voltage fitting error and the voltage measurement noise level.

24. The online estimator of claim 18, wherein the statistics represent an indication of validity of a measured battery current.

25. The online estimator of claim 18, wherein the statistics represent an average value of a prevailing current of the battery and a measure of variation of the prevailing current.

26. The online estimator of claim 18, wherein the indicator of validity of the battery current is defined by a measure of spectral content of the battery current and a measure of conditioning of the battery current data.

27. The online estimator of claim 18, wherein the estimation of the equivalent circuit model parameters may be configured to be performed on-demand or continuously.

28. The online estimator of claim 27, wherein when the estimation of the equivalent circuit model parameters is configured to be performed on-demand, the estimated equivalent circuit model parameters are published once the estimated equivalent circuit model is indicated to be valid.

29. The online estimator of claim 27, wherein when the estimation of the equivalent circuit model parameters is configured to be performed continuously, the estimated equivalent circuit model parameters are published at a preset periodicity.

30. The online estimator of claim 18, wherein the equivalent circuit model parameters comprise resistances associated with time constants of the equivalent circuit model.

31. The online estimator of claim 30, wherein the equivalent circuit model parameters further comprise capacitances associated with time constants of the equivalent circuit model.

32. The online estimator of claim 18, further comprising using the equivalent circuit model parameters in a predictive model to determine available power or a maximum current that can be drawn from the battery at a given moment in time.

33. The online estimator of claim 18, further comprising a predictive model configured to use the equivalent circuit model parameters to determine an extent of battery aging.

34. The online estimator of claim 18, wherein the online estimator is further configured to track nonlinear current-dependent equivalent circuit model parameters in a continuous manner.
